(19) United States
(12) Patent Application Publication
(10) Pub. No.: US 2011/0047902 A1
(43) Pub. Date: Mar. 3, 2011

(54) Photovoltaic shingle

(76) Inventor: Philip Cryar, Santa Rosa Beach, FL (US)

(21) Appl. No.: 12/584,241

(22) Filed: Sep. 3, 2009

(51) Int. Cl. H01L 31/048; E04D 13/18; H01L 31/042; E04D 1/12

(52) U.S. Cl. 52/173.3

(57) ABSTRACT

A photovoltaic shingle uses a tab shingle body onto which an electrical grid is disposed. A thin film photovoltaic film overlays the wire grid and is electrically coupled to the grid using the shingle body as its substrate. The grid is electrically coupled to a series of leads such that the leads electrically couple to a conduction strip that is attached to a roof underlayment, the strip making a horizontal run on the roof. Each conduction strip is electrically connected to an electrical subsystem that provides electricity for a building and/or transfers electricity to an electrical grid.

### BACKGROUND OF THE INVENTION

1. Field of the Invention

The present invention relates to a shingle used for roofing on a building wherein the shingle has a photovoltaic or solar cell for generating electricity such that the shingles of the roof act together to generate electricity for the building.

2. Background of the Prior Art

Humans depend on oil for a large portion of their energy needs. From powering land vehicles and ocean vessels to being used to fire electricity generating power plants, oil and its various distillates plays a major role in power generation for humans all over the world. However, oil is not without its shortcomings. First of all, oil is a finite resource that may eventually run out. Additionally, as recent events have shown, the price and availability of oil is subject to economic and geopolitical upheaval, causing disruptions in the lives of millions. Additionally, oil is typically considered a “non-green” energy source in that the use of oil generates relatively high pollution amounts.

Accordingly, man is trying to move away from oil as a major energy source into renewable and less polluting sources of energy. One such energy source being relied on is solar energy. Solar collector farms are popping up, which farms can generate sufficient electricity to power an entire city. However, such farms tend to be located in relatively desolate and non-forested regions. People living in more densely populated areas or areas with substantial forestation tend to look at smaller solar generation systems. One such smaller system is a single building solar collector system. Such a collector system typically sits atop the roof of the building in a sun facing direction such that solar cells within the system generate electricity whenever the sun shines onto the solar cells. The generated electricity, which is often either 12 or 24 volt DC is channeled into the building's electrical system either directly or via one or more batteries (in either case passing through an inverter to cover the direct current to 120 volt alternating current (or the current needed at the locale whereat the system resides)) so that during sunny periods, and even some non-sunny periods when batteries are used, the building's electrical needs are at least partially generated by the solar system so that the building does not need to draw its electricity needs off of the electrical grid. Additionally, many such systems are designed so as to pass any unused electricity generated back onto the power grid so that the building's occupants “sell back” electricity to the power company.

While such solar systems are one step in achieving a reduction in oil use, such systems still have certain shortcomings. Many single building solar systems are comprised of a series of rectangular panels that each hold a multitude of solar cells. Each panel is installed onto the roof and wired in appropriate fashion. One of the problems with such panels is that they are unsightly and many homeowners associations do not allow their use. Additionally, such panels are relatively heavy so that in addition to the costs of installations of the panels proper, the building owner may also need to have the roof structure of the building reinforced to be able to bear the added load created by the panels.

To address this problem, devices have been proposed wherein the solar cell is incorporated onto the shingle of the building so as to eliminate the large and rather unsightly collector panels. However, some such shingle systems require a protective glass or similar cover overtop the solar cell (such as crystalline solar cells) so that such cells are relatively thick and inflexible. This cell thickness makes such solar systems practical only for ceramic tile roofs. As many building are impractical for ceramic roofs, either due to aesthetics, strength of the roof, or due to the prohibition in the jurisdiction in which the building is located due to safety concerns from high wind events, such solar systems are impractical to many. Additionally, current systems require an elaborate grid system in order to electrically connect each shingle to the overall electrical system and to the building. Such grids and the labor associated with their installation, make such solar systems impractical for many. Such grids also suffer either partial or even total failure if one of the shingles ceases operation either through damage to the shingle during a storm, for example, or through natural life cycle expiration.

What is needed is a solar cell system for typical shingle roofed building that addresses the above mentioned shortcomings found in the art. Specifically, such a system must be relatively thin, flexible, and unobtrusive so as to not adversely impact the aesthetic appeal of the building. Such a system must be relatively straightforward to install without the need for an elaborate grid or substantial involvement of electricians. Such a system must be cost-effective so as to be readily affordable to building owners in the market for such solar systems.

### SUMMARY OF THE INVENTION

The photovoltaic shingle of the present invention addresses the aforementioned needs in the art by providing a shingle based solar cell for installation onto the roof of a building that is relatively thin so as not to detract from the aesthetic qualities of the building onto which the shingle is installed. By being flexible, the present invention is usable as a typical tar-based shingle. The photovoltaic shingle is relatively simple in design and construction so as to be relatively inexpensive to manufacture and purchase. The photovoltaic shingle relies on a very simple electrical grid for transferring the electricity produced from each shingle to the building's electrical system so that installation costs are kept reasonable. The photovoltaic shingle, when used on a roof, provides a solar system that is highly redundant so that a failure of any shingle in the overall system, is localized to that shingle and does not affect the remainder of the system.

The photovoltaic shingle of the present invention is comprised of a shingle body that has a front surface, a back surface, a top, a bottom, a first side, and a second side. A typical tar tab is located on the front surface and extends from the first side to the second side and is positioned between the top and the bottom. An electrically conductive wire grid is disposed on the front surface of the shingle body between the tar tab and the bottom. At least one lead is attached to the back surface of the shingle body above the tar tab such that each lead is electrically connected to the wire grid via connection wires that pass through the shingle body. A solar film is attached to the front surface of the shingle body below the tar tab and either overlays or underlays the wire grid and is electrically coupled to the wire grid such that any electricity generated by the solar film is transferred to the wire grid which in turn transfers the electricity to the leads. The solar film is a thin film solar film. A conduction strip is attached to a typical roof underlayment such that the one or more leads of each shingle are each electrically coupled to the conduction strip when installed on the roof of the building. The conduction strip is electrically coupled to an electrical subsystem which electrical subsystem transfers the electricity onward such as to a building for use therein (either directly or via a battery subsystem) or to an electrical grid. The conduction strip has an adhesive backing for facilitating attachment of the conduction strip to the roof underlayment. A transparent flexible plastic film overlays the solar film in order to protect the solar film.

### BRIEF DESCRIPTION OF THE DRAWINGS

FIG. 1 is a plan view of the photovoltaic shingle of the present invention

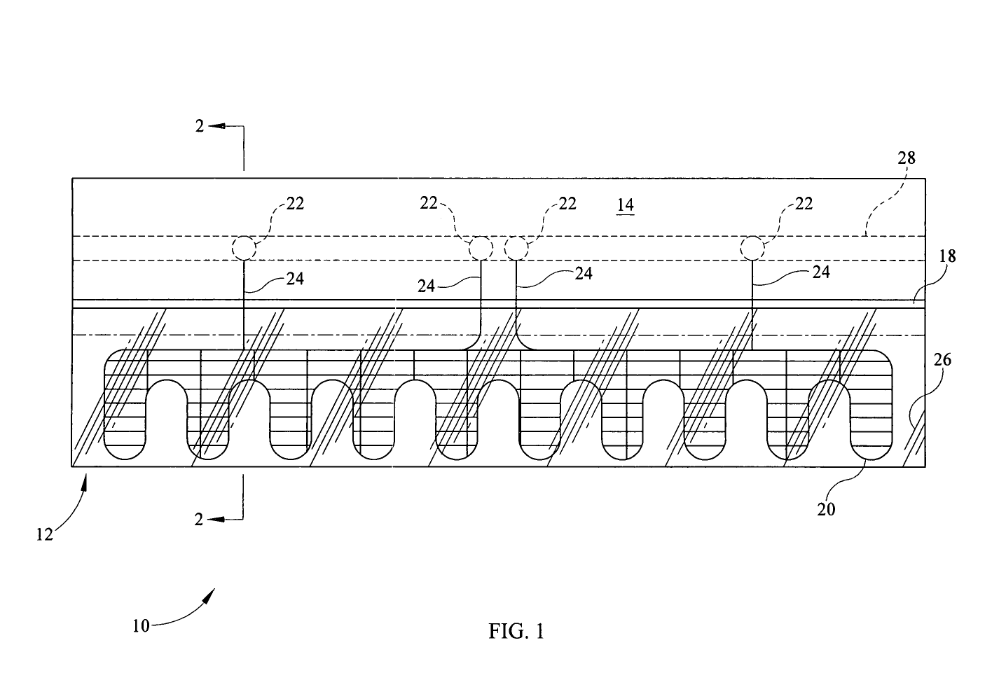

FIG. 2 is a side view, sectioned along line 2-2 in FIG. 1, of the photovoltaic shingle of FIG. 1.

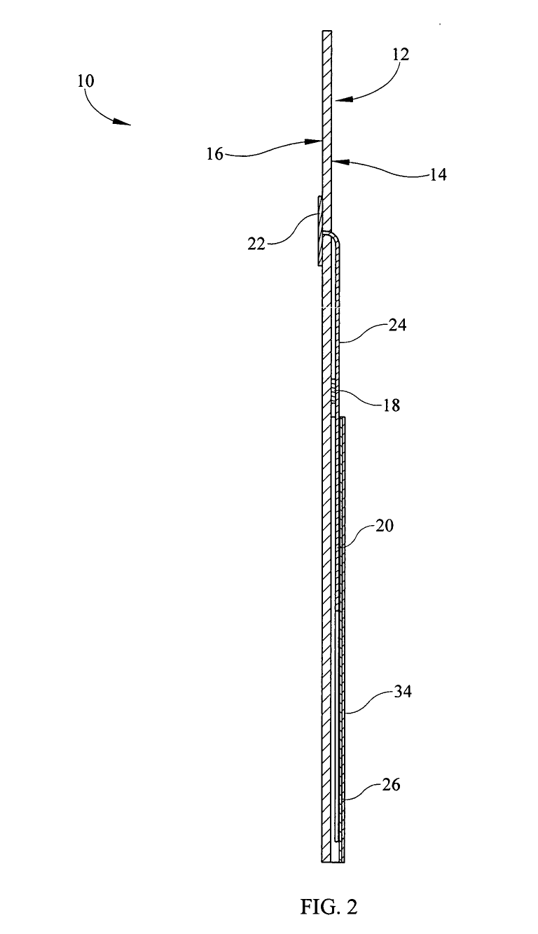

FIG. 3 is a plan view of the photovoltaic shingle used with a typical three-tab type of roof shingle.

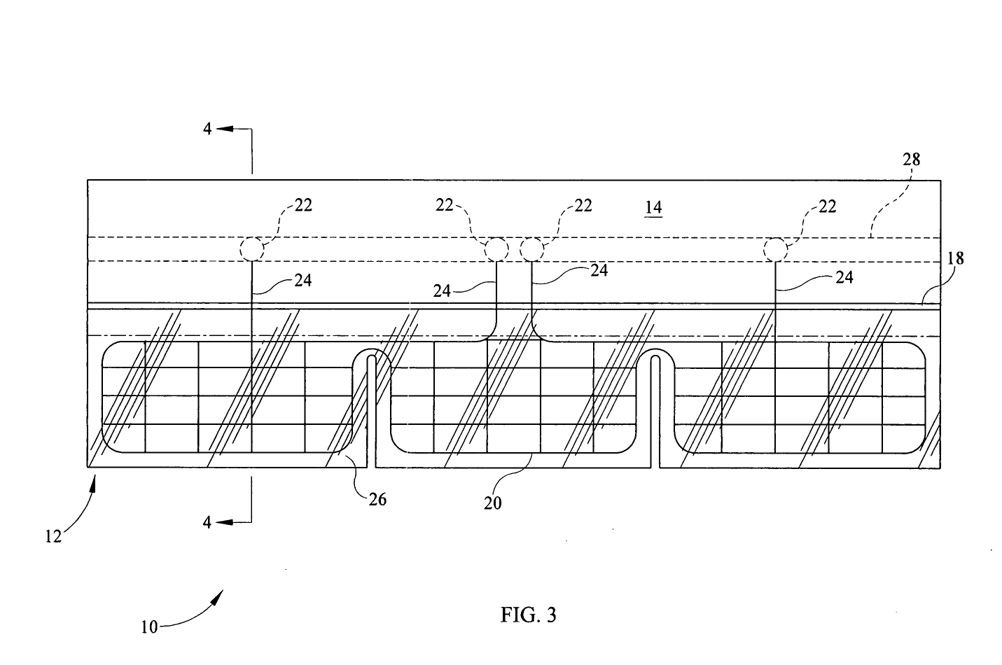

FIG. 4 is a side view, sectioned along line 4-4 in FIG. 3, of the photovoltaic shingle of FIG. 1.

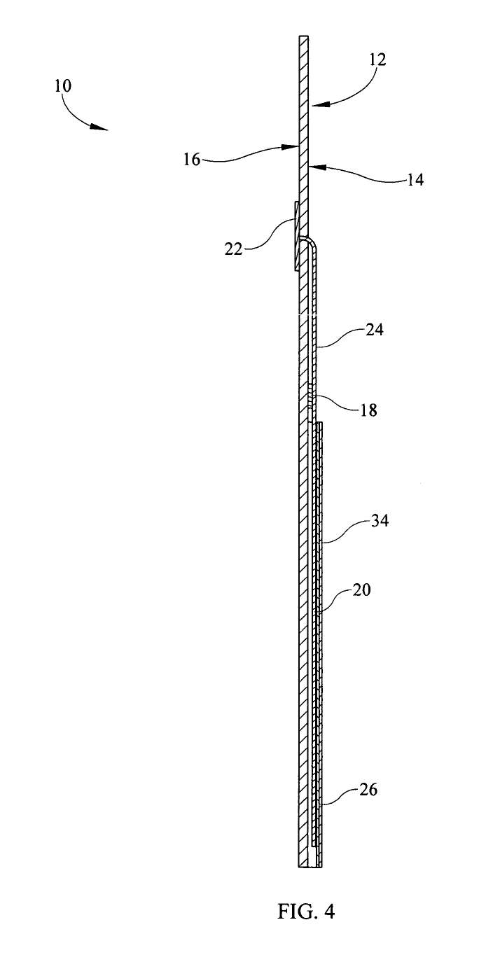

FIG. 5 is an environmental view of several of the photovoltaic shingles installed on a building.

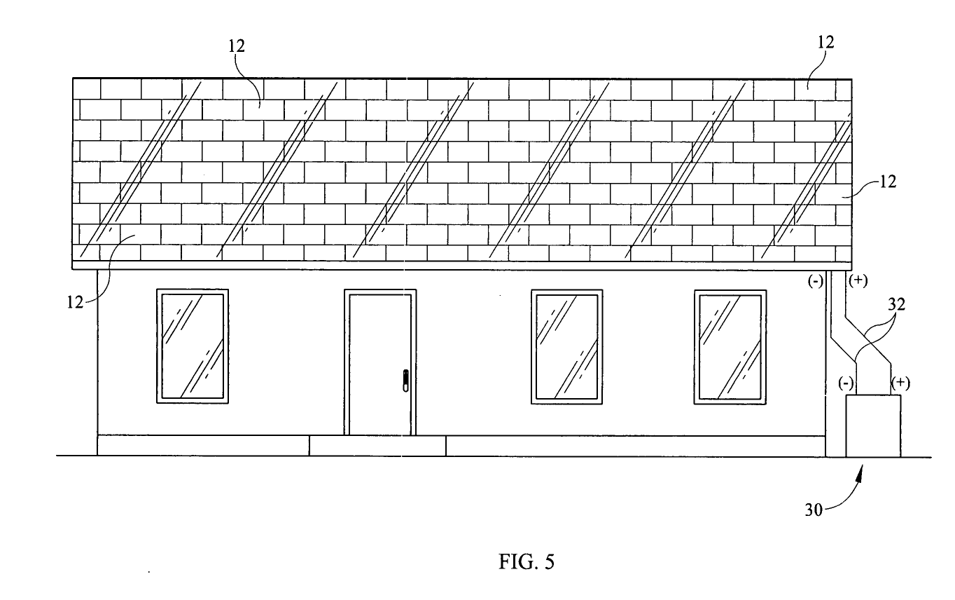

Similar reference numerals refer to similar parts throughout the several views of the drawings.

### DESCRIPTION OF THE PREFERRED EMBODIMENT

Referring now to the drawings, it is seen that the photovoltaic shingle of the present invention, generally denoted by reference numeral 10, is comprised of a typical tar based shingle body 12 having a front or outward facing surface 14 and a back or building facing surface 16. A conventional tar tab 18 is located on the front surface 14 of the shingle body 12. A wire grid 20 is disposed on the front surface 14 of the shingle body such that the wire grid 20 is electrically connected to a series of lead contacts 22 via a series of connection wires 24. The lead contacts 22 are located on the back surface 16 such that the connection wires 24 pass through the shingle body 12 to contact the leads 22. The wire grid 20 and the connection wires 24 are made from an appropriate electrical conduction material such as copper. Extending from proximate the bottom of the tar tab 18 and terminating proximate the bottom of the shingle body 12 is a photovoltaic or solar film 26 that overlays and is electrically connected to the wire grid 20 in appropriate fashion, although the solar film 26 may underlay (wire grid 20 on top) the wire grid 20. The solar film 26 is any appropriate thin film made from thin film solar cell material including cadmium telluride copper indium gallium selenide, amorphous silicon and micromorphous silicon. The shingle body 12 acts as the substrate for the solar film 26. Although the solar film 26 is typically a large-area, single layer p-n junction diode, the multipoint connection of the wire grid 20 to the output of the solar film 26 allows for redundancy within the shingle 10 should a portion of the shingle 10 fail during use. A transparent flexible plastic film 34 overlays the solar film 26 in order to protect the solar film 26

The photovoltaic shingle 10 of the present invention, by being physically similar to a standard tar based roof shingle, is installed in similar fashion to the standard shingle, with the exception of the fact that a conduction strip 28 is positioned onto the roof underlayment (not illustrated) which conduction strip 28 collects the electricity generated by each shingle 10 that is electrically connected to the conduction strip 28 and transfers the electricity to an electrical subsystem 30 of the overall solar system formed, via appropriate wires 32. The conduction strip 28 may have an adhesive layer so as to be adhesively attached to the roof underlayment. The characteristics of the electrical subsystem 30 are typical of the art for building based solar systems. The subsystem 30 may include batteries and their associated control systems or may be connected directly to the electrical grid via invertors, etc., as is well known in the art. The conduction strip 28 is a flexible member that has sufficient gauge for the amount of electricity generated by the shingles 10. Each shingle 10 in a given run is attached to the roof so that its lead contacts 22 are electrically coupled to the conduction strip 28. As each conduction strip 28 is mounted horizontally onto the roof underlayment, all shingles 10 along a horizontal run are disposed in series. If a particular run is of such length that the amperage and/or voltage produced by the shingles 10 is too great, then either some of the shingles on that run may be conventional non-solar shingles or the distal end of the conduction strip 28 is truncated. Each installation is specific to the roof architecture and the type of solar film 26 being used so that all such calculations are performed on site in the usual way.

While the invention has been particularly shown and described with reference to an embodiment thereof, it will be appreciated by those skilled in the art that various changes in form and detail may be made without departing from the spirit and scope of the invention.

I claim:

1. A photovoltaic shingle comprising:
a shingle body having a front surface, a back surface, a top, a bottom, a first side, and a second side;
a tar tab located on the front surface extending from the first side to the second side and disposed between the top and the bottom;
an electrically conductive wire grid disposed on the front surface between the tar tab and the bottom;
at least one lead attached to the back surface of the shingle with each lead electrically connected to the wire grid; and
a solar film attached to the front surface of the shingle body below the tar tab and either overlaying or underlaying the wire grid and electrically coupled to the wire grid such that electricity generated by the solar film is transferred to the wire grid which in turn transfers the electricity to the leads.

2. The photovoltaic shingle as in claim 1 wherein the solar film is a thin film solar film.

3. The photovoltaic shingle as in claim 1 further comprising:
a conduction strip adapted to be attached to a roof underlayment such that the lead is electrically coupled to the conduction strip;
an electrical subsystem electrically coupled to the conduction strip, the electrical subsystem adapted to transfer the electricity onward.

4. The photovoltaic shingle as in claim 3 wherein the conduction strip has an adhesive backing for facilitating attachment of the conduction strip to the roof underlayment.

5. The photovoltaic shingle as in claim 3 wherein the solar film is a thin film solar film.

6. The photovoltaic shingle as in claim 1 wherein the solar film is overlaid by a clear flexible protective film.
